(19) United States
(12) Patent Application Publication
(10) Pub. No.: US 2003/0215758 A1
(43) Pub. Date: Nov. 20, 2003

(54) Photosensitive polymer and chemically amplified resist composition comprising the same

(75) Inventors: Hyun-Woo Kim, Suwon-City (KR); Sang-Gyun Woo, Yongin-City (KR); Myoung-Ho Jung, Yongin-City (KR)

Correspondence Address: F. Chau & Associates, LLP, Suite 501, 1900 Hempstead Turnpike, East Meadow, NY, 11554, US

(73) Assignee: Samsung Electronics Co., Ltd.

(21) Appl. No.: 10/409,346

(22) Filed: Apr. 8, 2003

(30) Foreign Application Priority Data
May 7, 2002 (KR) 2002-25137

(51) Int. Cl. G03F 7/038; G03C 1/492; G03C 1/494

(52) U.S. Cl. 430/495.1; 430/270.1; 430/910

(57) ABSTRACT

A photosensitive polymer having hydrophobic and hydrophilic portions homogenously distributed therein and a resist composition comprising the photosensitive polymer. The photosensitive polymer having a formula:

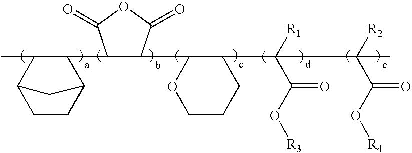

wherein R₁ and R₂ are independently a hydrogen atom or a methyl group, R₃ is an acid-labile C₄˜C₂₀ hydrocarbon group, R₄ is a hydrophilic group, a/(a+b+c+d+e)=0.01˜0.6, b/(a+b+c+d+e)=0.05˜0.7, c/(a+b+c+d+e)=0.01˜0.6, d/(a+b+c+d+e)=0.1˜0.5, and e/(a+b+c+d+e)=0.01˜0.5.

### CROSS-REFERENCE TO RELATED APPLICATION

This application claims priority to Korean Patent Application No. 2002-25137, filed on May 7, 2002, which is incorporated herein by reference.

### TECHNICAL FIELD OF THE INVENTION

The present invention generally relates to a photosensitive polymer and a chemically amplified resist composition. More particularly, the present invention relates to a photosensitive polymer having hydrophilic units and hydrophobic units evenly distributed within the polymer, and a resist composition comprising the same.

### BACKROUND OF THE INVENTION

As the manufacture of semiconductor devices becomes complicated and as semiconductor devices become more highly integrated, there is a need to form a fine pattern. Furthermore, with regard to semiconductor devices having a memory capacity of 1-Gigabit or more, a pattern size having a design rule of 0.2 μm or less is needed. For this reason, a lithography technique using a new exposure light source, ArF excimer laser (193 nm), has emerged.

However, compared to the conventional resist materials, resist materials used in lithography using ArF (193 nm) excimer laser have several limitations in commercial use. Particularly, such resist materials may have very low transparency and a very weak resistance against a dry etching process.

To date, (meth)acryl-based polymers have been typically used as resist materials in a lithography technique using an ArF excimer laser. In particular, representative examples of such polymers include poly(methyl methacrylate-tert-butyl methacrylate-methacrylic acid) available from IBM Corp. However, such polymers also potentially suffer from several drawbacks, specifically, poor resistance to dry etching.

Accordingly, one solution to enhance dry etching resistance is to introduce alicyclic compounds having a strong resistance to dry etching, for example, an isobornyl, adamantyl or tricyclodecanyl group, to the backbone of a polymer. However, since only a small portion of the polymer is occupied by the alicyclic compound, resistance to dry etching is still weak. Also, since the alicyclic compounds are strongly hydrophobic, the affinity to a developer solution is reduced. Thus, if such an alicyclic compound is contained in a terpolymer, adhesion to underlying materials of a resist layer obtained from the terpolymer may deteriorate.

To overcome the drawbacks stated above, there has been proposed a tetrapolymer having a carboxylic acid group introduced to the backbone of a polymer, as disclosed in J. Photopolym. Sci. Technol., 7(3), 507 (1994), the tetrapolymer having a formula:

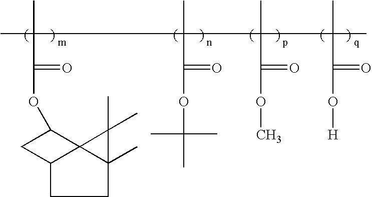

The resist layer obtained from the polymer having the above structure has a weak adhesion to the underlying layer materials and poor resistance to dry etching. Also, the resist layer is disadvantageous in that a generally used developer solution must be diluted to be used for development.

As another conventional polymer, a methacrylate copolymer having an alicyclic protecting group having the following formula has been proposed, as disclosed in J. Photopolym. Sci. Technol., 9(3), p.509 (1996):

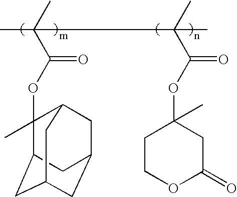

This polymer has an adamantyl group, which contributes to enhancing resistance to dry etching, and a lactone group, which improves adhesiveness, in its methacrylate backbone. As a result, the resolution of the resist and the depth of focus have improved. However, resistance to dry etching is still weak, and serious line edge roughness is observed after line patterns are formed from the resist layer. Another drawback of the polymer having the formula shown above is that the raw material used to synthesis the polymer is expensive. In particular, the manufacturing cost of a polymer having a lactone group, which is introduced to improve adhesiveness, is so high that its use as a resist is not practical. Therefore, there is a need for a new polymer capable of replacing costly polymers.

As an example of another conventional resist composition, a cycloolefin-maleic anhydride (COMA) alternating polymer having the following formula has been suggested (J. Photopolym. Sci. Technol., Vol. 12(4), pp. 553 (1999), and U.S. Pat. No. 5,843,624):

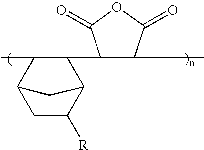

In the production of a copolymer, such as a COMA having the formula shown above, the production cost of raw materials is cheap, but the production yield of the polymer sharply decreases. In addition, the transmittance of the polymer is very low at a short wavelength region, for example at 193 nm. The synthetic polymers have in their backbone the alicyclic group, which shows prominent hydrophobicity, and as a result, adhesiveness to neighboring material layers is very poor.

Also, these polymers have a glass transition temperature of 200° C. or more due to the structural characteristic of their backbones. As a result, it is difficult to achieve an annealing effect for eliminating a free volume from the resist layer formed of the polymer with the above structure during baking. Accordingly, the resist layer has several drawbacks including low environmental stability and T-top profile. Also, environmental resistance is lowered even at post-exposure delay (PED).

To solve these problems, the present inventors proposed the use of a copolymer of alkyl vinyl ether and maleic anhydride. While the copolymer of alkyl vinyl ether and maleic anhydride is cheap and its dry etching resistance is strong, the copolymer is hydrophilic, and therefore, it could only function primarily as a photosensitive polymer having good adhesion to underlying material layers.

In practice, for forming a fine pattern requiring a smaller line width, e.g., about 100 nm or less, a resist composition comprising a copolymer containing a hydrophobic monomer, maleic anhydride, and a hydrophilic monomer, is widely used. The hydrophobic monomer, introduced for increasing resistance to dry etching, has a multi-cyclic hydrocarbon group, such as an adamantyl, tricyclodecyl or norbornyl. The maleic anhydride is introduced for improving adhesion to underlying material layers. The hydrophilic monomer has a polar group, such as vinyl ether. However, in a mixed system of a hydrophobic group for increasing resistance to dry etching and a hydrophilic group for improving adhesiveness, a phase separation between a hydrophobic portion and a hydrophilic portion is created, making it difficult to create a homogenous polymerization. Also, a homopolymer or a undesired block copolymer may be easily produced in a polymerization product. When such a polymerization product is used as a resist composition material, solubility to a developer solution in a resist layer becomes inhomogeneous, causing a bridging defect in a pattern. Also, a resist layer may be peeled off at the hydrophobic portion of the resist material, resulting in pattern collapse. Further, swelling may occur at a strongly hydrophilic portion of a resist layer due to the excessive infiltration of a developer solution.

### SUMMARY OF THE INVENTION

The present invention provides a photosensitive polymer having hydrophobic and hydrophilic portions homogenously distributed therein to provide improved resolution while minimizing bridging defects, peeling off, swelling and the like when used as a resist material in a photolithography process for forming a fine pattern.

The present invention also provides a resist composition which can provide excellent lithographic performance in a photolithography process using a light exposure source at a short-wavelength region, e.g., about 193 nm, as well as a deep UV region, e.g., about 248 nm, and can prevent generation of defects such as bridging defect occurring at a reduced line width, e.g., about 100 nm or less.

According to an embodiment of the present invention, there is provided a photosensitive polymer having a formula 1:

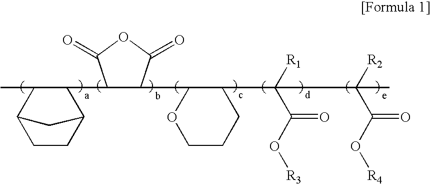

wherein R₁ and R₂ are independently a hydrogen atom or a methyl group, and R₃ is an acid-labile C₄*C₂₀ hydrocarbon group, R₄ is a hydrophilic group, a/(a+b+c+d+e)=0.01˜0.6, b/(a+b+c+d+e)=0.05˜0.7, c/(a+b+c+d+e)=0.01˜0.6, d/(a+b+c+d+e)=0.1˜0.5, and e/(a+b+c+d+e)=0.01˜0.5.

The photosensitive polymer has a weight average molecular weight of about 3,000 to about 100,000.

Preferably, R₄ is a group containing at least one structure selected from the group consisting of a hydroxy, carboxyl, ether, lactone and hyperlactone group. More preferably, R₄ has at least one structure selected from the group consisting of

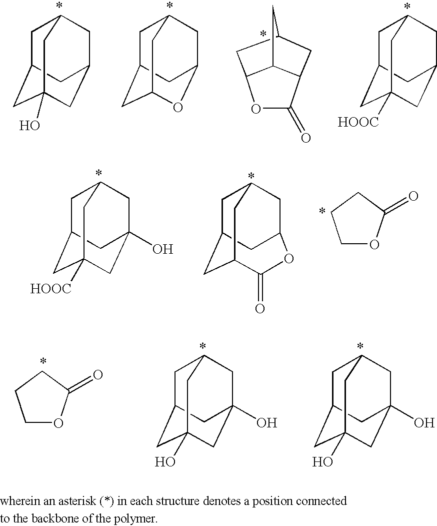

In a photosensitive polymer according to an embodiment of the present invention, R₃ is t-butyl or tetrahydropyranyl. Also, R₃ may be an acid-labile alicyclic hydrocarbon group, exemplified by 2-methyl-2-norbornyl, 2-ethyl-2-norbornyl, 2-methyl-2-isobornyl, 2-ethyl-2-isobornyl, 8-methyl-8-tricyclo[5.2.1.0^{2,6}]decanyl, 8-ethyl-8-tricyclo[5.2.1.0^{2,6}]decanyl, 2-methyl-2-adamantyl, 2-ethyl-2-adamantyl, 2-methyl-2-fenchyl or 2-ethyl-2-fenchyl.

According to another embodiment of the present invention, there is provided a resist composition comprising a photosensitive polymer having the formula 1, and a photoacid generator (PAG).

The PAG is preferably contained in an amount of about 0.5 wt % to about 20 wt % based on the total weight of the photosensitive polymer. Preferably, the PAG comprises triarylsulfonium salts, diaryliodonium salts, sulfonates or any combination thereof.

A resist composition according to another embodiment of the present invention may further include an organic base. The organic base may be contained in an amount of about 0.5 to about 50 mol % based on the amount of the PAG.

Preferably, the organic base includes a tertiary amine compound. Examples of the organic base include triethylamine, triisobutylamine, triisooctylamine, triisodecylamine, diethanolamine, triethanolamine, N-alkyl substituted pyrrolidinone, N-alkyl substituted caprolactam, N-allyl caprolactam, N-alkyl substituted valerolactam and any combination thereof.

A photosensitive polymer according to another embodiment of the present invention has a structure in which hydrophilic units and hydrophobic units are copolymerized so as to be alternately linked so that hydrophobic and hydrophilic portions are homogenously distributed. Homogeneity of the copolymer contained in the resist composition prepared using the photosensitive polymer according to the present invention having such a structure can reduce the possibility of generating bridging defects and peeling off or swelling of a resist layer during a photolithography process for forming a fine pattern with a line width of about 100 nm or less. Thus, the formed resist composition exhibits excellent lithographic performance and can be advantageously in manufacturing next-generation semiconductor devices.

### DETAILED DESCRIPTION OF PREFERRED EMBODIMENTS

A photosensitive polymer according to an embodiment of the present invention includes the structure of the formula 1. The photosensitive polymer according to the present invention having the formula 1, preferably comprises units represented by formulas 2 through 6:

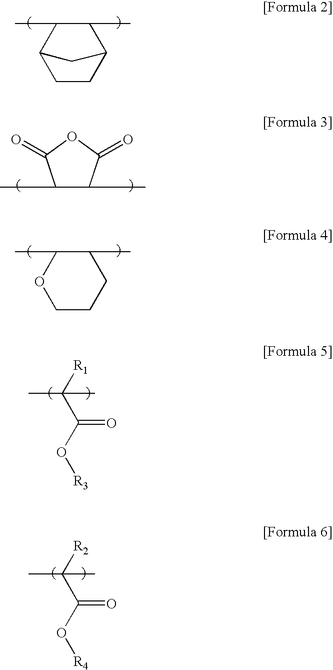

Among the respective units represented by the formulas 2 through 6, the units represented by the formulas 2 and 5 are hydrophobic, while the units represented by the formulas 3, 4 and 6 are hydrophilic. As described above, the photosensitive polymer according to the present invention has a structure in which hydrophilic units and hydrophobic units are copolymerized so as to be alternately linked so that hydrophobic and hydrophilic portions are homogenously distributed. Homogeneity of the copolymer contained in the resist composition prepared using the photosensitive polymer according to the present invention having such a structure that can reduce the possibility of generating bridging defects, peeling off or swelling during a photolithography process for forming a fine pattern, compared to the case of using the conventional resist composition.

According to another embodiment of the present invention, a photosensitive polymer contained in the resist composition, as represented by the formula 1, comprises a copolymer prepared using alternating polymerization of a hydrophobic norbornene monomer unit and a hydrophilic maleic anhydride monomer unit and simultaneously using a hydrophilic (meth)acrylate monomer unit and a hydrophobic (meth)acrylate monomer unit having a similar reactive ratio.

A photosensitive polymer according to another embodiment of the present invention can be prepared using conventional radical polymerization, other cationic polymerization, or anionic polymerization.

According to another embodiment of the present invention, a resist composition may be prepared with copolymers having formulas 2-6 and a PAG are dissolved in various types of solvents, including propylene glycol monomethyl ether acetate (PGMEA), ethyl lactate, cyclohexanone and the like, to prepare resist solutions. The solid content contained in each resist solution is about 10 to about 20 wt % based on the weight of the solvent. According to another embodiment of the present invention, an organic base comprising amines may be added in an amount of about 0.5 to about 50 mol % based on the amount of PAG. Also, to control the overall dissolution rate of the resist, the resist composition of exemplary embodiments may further include about 5 to about 25 wt % of a dissolution inhibitor, based on the weight of the photosensitive polymer.

The PAG is added in an amount of about 0.5 to about 20 wt % based on the weight of the photosensitive polymer. As the PAG, inorganic onium salts or organic onium salts may be used each alone or any combination thereof. Examples of the PAG include triarylsulfonium triflate, diaryliodonium triflate, triarylsulfonium nonaflate, diaryliodonium nonaflate, succinimidyl triflate, 2,6-dinitrobenzyl sulfonate, and the like.

For a lithography process, the resist solution is first filtered twice using a 0.2 μm membrane filter to obtain a resist composition.

The obtained resist composition is subjected to the following process to pattern a silicon wafer.

First, either a bare silicon wafer or a silicon wafer having an underlying layer, such as a silicon oxide layer, silicon nitride layer or silicon oxynitride layer, to be patterned thereon is prepared and treated with hexamethyldisilazane (HMDS). Thereafter, the underlying layer is coated with the resist composition to a thickness of about 0.2 to about 0.7 μm to form a resist layer.

The silicon wafer having the resist layer is pre-baked at a temperature in the range of about 90° C. to about 150° C. for about 60 to about 120 seconds to remove a solvent, followed by exposure using various types of exposure light sources, e.g., deep UV (KrF or ArF), extreme UV, E-beam or X-ray. Next, in order to induce a chemical reaction at an exposed portion of the resist layer, post-exposure baking (PEB) is performed at a temperature in the range of about 90° C. to about 150° C. for about 60 to about 120 seconds.

As a result, the exposed portion exhibits very high solubility to a developing solution including 2.38 wt % tetramethylammonium hydroxide (TMAH). Thus, during development, the exposed portion is dissolved. In the case of using an ArF excimer laser, a 0.3 to 0.15 μm line and space pattern can be formed at an exposure dose of about 5 to about 30 mJ/cm².

The underlying layer such as the silicon oxide layer to be patterned is etched by a special etching gas, such as plasma, e.g., a halogen or CₓF_{y} gas, using the resultant resist pattern as a mask. Subsequently, the resist pattern remaining on the wafer is removed by washing and by a wet process using a stripper, thereby forming a desired silicon oxide pattern.

Illustrative exemplary embodiments of the present invention will be described in detail with reference to the following examples and synthesis examples, and what can be technically deduced by one skilled in the art is not described herein. It is noted that reagents used for explaining the invention are generally available, and most are available from Aldrich Chemical Co. Particular reagents which are not commercially available can be easily synthesized using the technology reported in Proc. SPIE Vol. 4345, p. 87 (2001) or Proc. SPIE Vol. 3999, p. 1147 (2000).

### EXAMPLE 1

Synthesis of Polymer

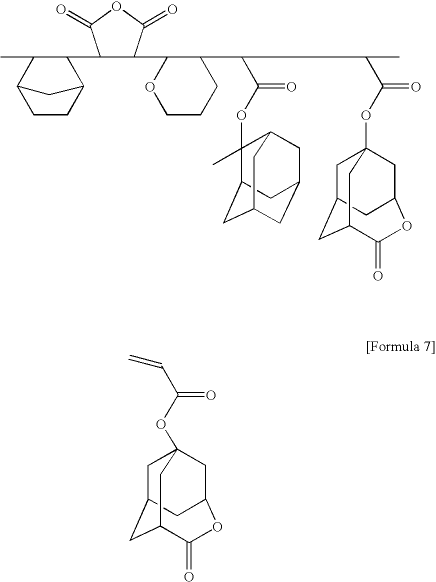

2.1 g (25 mmol) of 3,4-dihydro-2H-pyrane, 7.35 g (75 mmol) of refined maleic anhydride, 4.7 g (50 mmol) of norbornene, 11 g (50 mmol) of 2-methyl-2-adamantyl acrylate, 11.8 g (50 mmol) of a monomer represented by a formula 7, and 0.33 g of 2,2′-azobisisobutyronitrile (AIBN) were put into a one-necked round-bottom flask to be dissolved in about 50 g of anhydrous THF, followed by degassing by performing 3 freeze-pump thaw cycles in a liquid nitrogen bath, and then sealing the flask after the 3 freeze-pump thaw cycles are completed. Thereafter, the resulting product was polymerized in an oil bath maintained at about 65° C. for about 24 hours.

After the polymerization reaction was completed, an appropriate amount (e.g., about 50 mL) of Tetrahydrofuran (THF) was added to the reaction product to be dissolved. Then, the reaction product was slowly dropped into and precipitated in excess (10-fold) n-hexane. The precipitate was dissolved again in about 50 mL of THF and then re-precipitated twice in a mixed solution of n-hexane and isopropyl alcohol (IPA) in a mixture ratio of about 8:2. The obtained filtrate was dried in a vacuum oven maintained at about 50° C. for about 24 hours to give a desired copolymer with a yield of about 80%.

The resultant product had a weight average molecular weight (Mw) of about 7,800 and a polydispersity (Mw/Mn) of about 1.8.

### EXAMPLE 2

Synthesis of Polymer

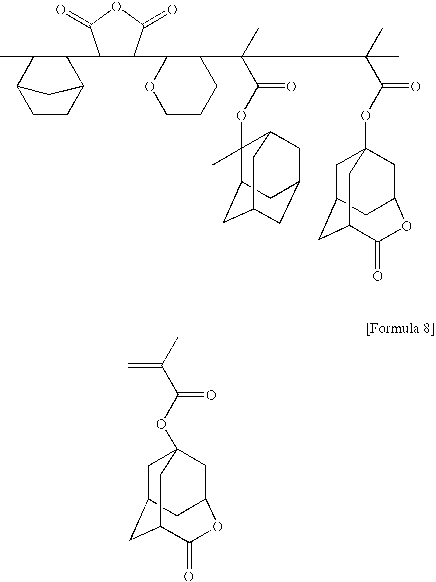

2.1 g (25 mmol) of 3,4-dihydro-2H-pyrane, 7.35 g (75 mmol) of refined maleic anhydride, 4.7 g (50 mmol) of norbornene, 11.7 g (50 mmol) of 2-methyl-2-adamantyl methacrylate, 12.5 g (50 mmol) of a monomer represented by a formula 8, and 0.33 g of AIBN were put into a one-necked round-bottom flask to be dissolved in about 50 g of anhydrous THF, followed by degassing by performing 3 freeze-pump thaw cycles in a liquid nitrogen bath, and then sealing the flask after the 3 freeze-pump thaw cycles are completed. Thereafter, the resulting product was polymerized in an oil bath maintained at about 65° C. for about 24 hours.

After the polymerization reaction was completed, an appropriate amount (e.g., about 50 mL) of THF was added to the reaction product to be dissolved. Then, the reaction product was slowed dropped into and precipitated in excess (10-fold) n-hexane. The precipitate was dissolved again in about 50 mL of THF, and then re-precipitated twice in a mixed solution of n-hexane and isopropyl alcohol (IPA) in a mixture ratio of about 8:2. The obtained filtrate was dried in a vacuum oven maintained at about 50° C. for about 24 hours to give a desired copolymer with a yield of about 82%.

The resultant product had a weight average molecular weight (Mw) of about 8,800 and a polydispersity (Mw/Mn) of about 1.8.

### EXAMPLE 3

Synthesis of Polymer

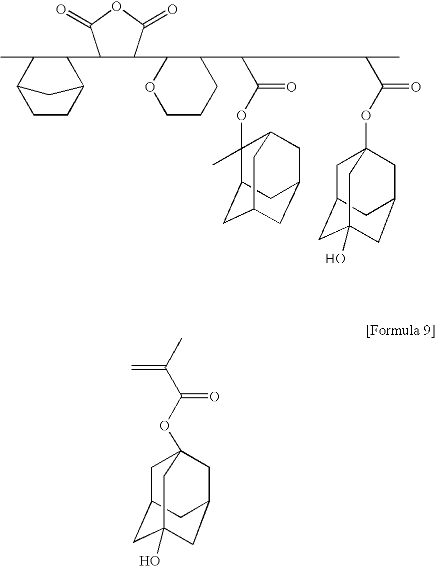

2.1 g (25 mmol) of 3,4-dihydro-2H-pyrane, 7.35 g (75 mmol) of refined maleic anhydride, 4.7 g (50 mmol) of norbornene, 11.7 g (50 mmol) of 2-methyl-2-adamantyl methacrylate, 11.8 g (50 mmol) of a monomer represented by a formula 9, and 0.33 g of AIBN were put into a one-necked round-bottom flask to be dissolved in about 50 g of anhydrous THF, followed by degassing by performing 3 freeze-pump thaw cycles in a liquid nitrogen bath, and then sealing the flask after the 3 freeze-pump thaw cycles are completed. Thereafter, the resulting product was polymerized in an oil bath maintained at about 65° C. for approximately 24 hours.

After the polymerization reaction was completed, an appropriate amount (e.g., about 50 mL) of THF was added to the reaction product to be dissolved. Then, the reaction product was slowed dropped into and precipitated in excess (10-fold) n-hexane. The precipitate was dissolved again in about 50 mL of THF, and then re-precipitated twice in a mixed solution of n-hexane and isopropyl alcohol (IPA) in a mixture ratio of about 8:2. The obtained filtrate was dried in a vacuum oven maintained at about 50° C. for about 24 hours to give a desired copolymer with a yield of about 81%.

The resultant product had a weight average molecular weight (Mw) of about 9,700 and a polydispersity (Mw/Mn) of about 1.8.

### EXAMPLE 4

Synthesis of Polymer

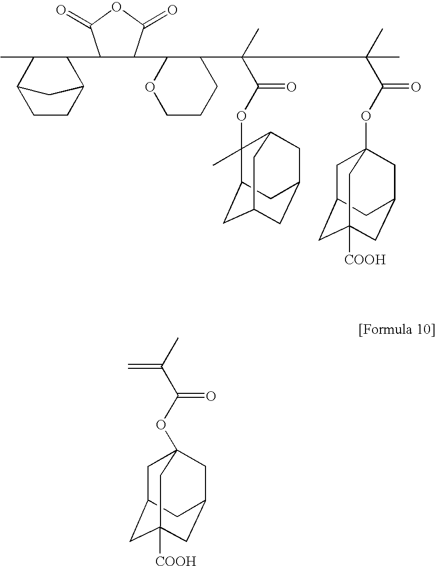

2.1 g (25 mmol) of 3,4-dihydro-2H-pyrane, 7.35 g (75 mmol) of refined maleic anhydride, 4.7 g (50 mmol) of norbornene, 11.7 g (50 mmol) of 2-methyl-2-adamantyl methacrylate, 13.3 g (50 mmol) of a monomer represented by a formula 10, and 0.33 g of AIBN were put into a one-necked round-bottom flask to be dissolved in about 60 g of anhydrous THF, followed by degassing by performing 3 freeze-pump thaw cycles in a liquid nitrogen bath, and then sealing the flask after the 3 freeze-pump thaw cycles are completed. Thereafter, the resulting product was polymerized in an oil bath maintained at about 70° C. for about 24 hours.

After the polymerization reaction was completed, an appropriate amount (e.g., about 50 mL) of THF was added to the reaction product to be dissolved. Then, the reaction product was slowed dropped into and precipitated in excess (10-fold) n-hexane. The precipitate was dissolved again in about 50 mL of THF and then re-precipitated twice in a mixed solution of n-hexane and isopropyl alcohol (IPA) in a mixture ratio of about 8:2. The obtained filtrate was dried in a vacuum oven maintained at about 50° C. for about 24 hours to give a desired copolymer with a yield of about 85%.

The resultant product had a weight average molecular weight (Mw) of about 12,000 and a polydispersity (Mw/Mn) of about 1.7.

### EXAMPLE 5

Synthesis of Polymer

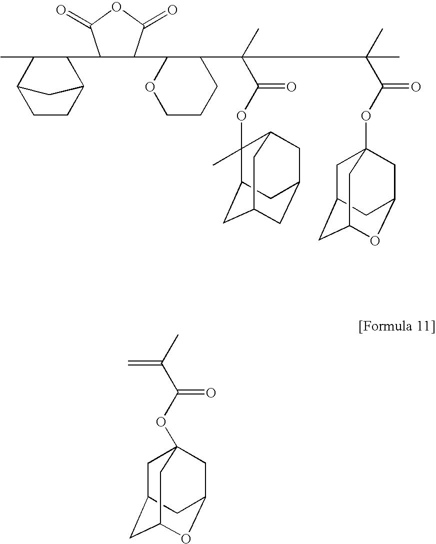

2.1 g (25 mmol) of 3,4-dihydro-2H-pyrane, 7.35 g (75 mmol) of refined maleic anhydride, 4.7 g (50 mmol) of norbornene, 11.7 g (50 mmol) of 2-methyl-2-adamantyl methacrylate, 11.2 g (50 mmol) of a monomer represented by a formula 11, and 0.33 g of AIBN were put into a one-necked round-bottom flask to be dissolved in about 60 g of anhydrous THF, followed by degassing by performing 3 freeze-pump thaw cycles in a liquid nitrogen bath, and then sealing the flask after the three freeze-pump thaw cycles were completed. Thereafter, the resulting product was polymerized in an oil bath maintained at about 70° C. for approximately 24 hours.

After the polymerization reaction was completed, an appropriate amount (e.g., about 50 mL) of THF was added to the reaction product to be dissolved. Then, the reaction product was slowed dropped into and precipitated in excess (10-fold) n-hexane. The precipitate was dissolved again in about 50 mL of THF and then re-precipitated twice in a mixed solution of n-hexane and isopropyl alcohol (IPA) in a mixture ratio of about 8:2. The obtained filtrate was dried in a vacuum oven maintained at about 50° C. for about 24 hours to give a desired copolymer with a yield of about 83%.

The resultant product had a weight average molecular weight (Mw) of about 8,000 and a polydispersity (Mw/Mn) of about 1.7.

### EXAMPLE 6

Preparation of Resist Composition and Lithographic Performance

1.0 g of the polymer synthesized in Example 1, 10 mg triphenylsulfonium trifluoromethanesulfonate(triflate) as a photoacid generator (PAG) and triisobutylamine as an organic base were completely dissolved in about 8 g of a cyclohexanone solvent. The organic base was added in an amount of about 20 mol % based on the amount of the PAG. Then, the reaction product was filtered using a 0.2 μm membrane filter, to give a resist composition. The resist composition was coated to a thickness of about 0.3 μm on a bare silicon wafer treated with hexamethyidisilazane (HMDS) at approximately 3000 rpm.

Thereafter, the resulting wafer was pre-baked at a temperature of about 120° C. for about 90 seconds and exposed using an ArF excimer laser stepper (produced by ISI Co., NA=0.6, σ=0.7), followed by subjecting to post-exposure bake (PEB) at a temperature of about 120° C. for about 60 seconds.

Thereafter, the resulting wafer was developed with a 2.38 wt % tetramethylammonium hydroxide (TMAH) solution for about 60 seconds to form a resist pattern. The result showed that a 0.18 μm line-and-space pattern was obtained at an exposure dose of about 15 mJ/cm².

### EXAMPLE 7

Preparation of Resist Composition and Lithographic Performance

1.0 g of the polymer synthesized in Example 1, 5 mg triphenylsulfonium triflate and 10 mg triphenylsulfonium nonafluorobuthanesulfonate(nonaflate) as PAGs and N-allyl caprolactam as an organic base were completely dissolved in about 8 g of a cyclohexanone solvent. The organic base was added in an amount of about 30 mol % based on the total amount of the PAGs. Then, the reaction product was filtered using a 0.2 μm membrane filter, to give a resist composition. The resist composition was coated to a thickness of about 0.3 μm on a bare silicon wafer treated with HMDS at about 3000 rpm.

Thereafter, the resulting wafer was pre-baked at a temperature of about 120° C. for about 90 seconds and exposed using an ArF excimer laser stepper (produced by ISI Co., NA=0.6, σ=0.7), followed by performing PEB at a temperature of about 120° C. for about 60 seconds.

Thereafter, the resulting wafer was developed with a 2.38 wt % TMAH solution for about 60 seconds to form a resist pattern. The result showed that a 0.13 μm line-and-space pattern was obtained at an exposure dose of about 17 mJ/cm².

### EXAMPLE 8

Preparation of Resist Composition and Lithographic Performance

1.0 g of the polymer synthesized in Example 2, 10 mg triphenylsulfonium triflate as a PAG and triisodecylamine as an organic base were completely dissolved in about 8 g of a cyclohexanone solvent. The organic base was added in an amount of about 15 mol % based on the amount of the PAG. Then, the reaction product was filtered using a 0.2 μm membrane filter, to give a resist composition. The resist composition was coated to a thickness of about 0.3 μm on a bare silicon wafer treated with HMDS at approximately 3000 rpm.

Thereafter, the resulting wafer was pre-baked at a temperature of about 120° C. for about 90 seconds and exposed using an ArF excimer laser stepper (produced by ISI Co., NA=0.6, σ=0.7), followed by performing PEB at a temperature of about 120° C. for about 60 seconds.

Thereafter, the resulting wafer was developed with a 2.38 wt % TMAH solution for about 60 seconds to form a resist pattern. The result showed that a 0.14 μm line-and-space pattern was obtained at an exposure dose of about 18 mJ/cm².

### EXAMPLE 9

Preparation of Resist Composition and Lithographic Performance

1.0 g of the polymer synthesized in Example 3, 5 mg triphenylsulfonium nonaflate as a PAG and triisobutylamine as an organic base were completely dissolved in about 8 g of a cyclohexanone solvent. The organic base was added in an amount of about 20 mol % based on the amount of the PAG. Then, the reaction product was filtered using a 0.2 μm membrane filter, to give a resist composition. The resist composition was coated to a thickness of about 0.3 μm on a bare silicon wafer treated with HMDS at approximately 3000 rpm.

Thereafter, the resulting wafer was pre-baked at a temperature of about 120° C. for about 90 seconds and exposed using an ArF excimer laser stepper (produced by ISI Co., NA=0.6, σ=0.7), followed by performing PEB at a temperature of about 120° C. for about 90 seconds.

Thereafter, the resulting wafer was developed with a 2.38 wt % TMAH solution for about 60 seconds to form a resist pattern. The result showed that a 0.18 μm line-and-space pattern was obtained at an exposure dose of about 26 mJ/cm².

### EXAMPLE 10

Preparation of Resist Composition and Lithographic Performance

1.0 g of the polymer synthesized in Example 4, 5 mg triphenylsulfonium triflate and 10 mg triphenylsulfonium nonafluorobuthanesulfonate(nonaflate) as PAGs and N-allyl caprolactam as an organic base were completely dissolved in about 8 g of a cyclohexanone solvent. The organic base was added in an amount of about 30 mol % based on the amount of the PAG. Then, the reaction product was filtered using a 0.2 μm membrane filter, to give a resist composition. The resist composition was coated to a thickness of about 0.27 μm on a bare silicon wafer treated with HMDS at about 3000 rpm.

Thereafter, the resulting wafer was pre-baked at a temperature of about 120° C. for about 60 seconds and exposed using an ArF excimer laser scanner (ASML/1100, NA=0.75, σ=0.55/0.85), followed by performing PEB at a temperature of about 120° C. for about 60 seconds.

Thereafter, the resulting wafer was developed with a 2.38 wt % TMAH solution for about 60 seconds to form a resist pattern. The result showed that a 0.1 μm line-and-space pattern was obtained at an exposure dose of about 26 mJ/cm².

### EXAMPLE 11

Preparation of Resist Composition and Lithographic Performance

1.0 g of the polymer synthesized in Example 5, 5 mg triphenylsulfonium triflate and 10 mg triphenylsulfonium nonafluorobuthanesulfonate(nonaflate) as PAGs and N-allyl caprolactam as an organic base were completely dissolved in about 8 g of a cyclohexanone solvent. The organic base was added in an amount of about 30 mol % based on the amount of the PAG. Then, the reaction product was filtered using a 0.2 μm membrane filter, to give a resist composition. The resist composition was coated to a thickness of about 0.27 μm on a bare silicon wafer treated with HMDS at about 3000 rpm.

Thereafter, the resulting wafer was pre-baked at a temperature of about 120° C. for about 60 seconds and exposed using an ArF excimer laser scanner (ASML/1100, NA=0.75, σ=0.55/0.85), followed by performing PEB at a temperature of about 120° C. for about 60 seconds.

Thereafter, the resulting wafer was developed with a 2.38 wt % TMAH solution for about 60 seconds to form a resist pattern. The result showed that a 96 nm line-and-space pattern was obtained at an exposure dose of about 25 mJ/cm².

A photosensitive polymer contained in the resist composition according to another embodiment of the present invention comprises a copolymer prepared using alternating polymerization of a hydrophobic norbornene monomer unit and a hydrophilic maleic anhydride monomer unit and simultaneously using a hydrophilic methacrylate monomer unit and a hydrophobic methacrylate monomer unit having a similar reactive ratio. Thus, the photosensitive polymer according to the present invention has hydrophobic and hydrophilic portions homogenously distributed therein. The resist composition prepared from the photosensitive polymer according to the present invention has a structure in which hydrophilic units and hydrophobic units are copolymerized so as to be alternately linked so that hydrophobic and hydrophilic portions are homogenously distributed. Homogeneity of the copolymer contained in the resist composition prepared using the photosensitive polymer according to the present invention having such a structure exhibits uniform solubility to a developer solution and has good adhesion to underlying layers and excellent resolution. Thus, the generation of bridging defects and peeling off or swelling of a resist layer are reduced during a photolithography process for forming a fine pattern with a line width of about 100 nm or less.

The resist composition according to the present invention exhibits excellent lithographic performance when used in a photolithography process using a light exposure source at a short-wavelength area, e.g., 193 nm, as well as a deep UV region, e.g., 248 nm, thereby being advantageously used in manufacturing next-generation semiconductor devices.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A photosensitive polymer having a formula: 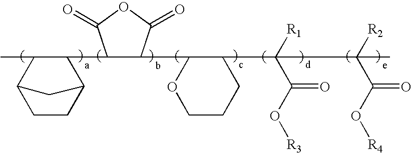
wherein R₁ and R₂ are independently a hydrogen atom or a methyl group, R₃ is an acid-labile C₄˜C₂₀ hydrocarbon group, R₄ is a hydrophilic group, a/(a+b+c+d+e)=0.01˜0.6, b/(a+b+c+d+e)=0.05˜0.7, c/(a+b+c+d+e)=0.01˜0.6, d/(a+b+c+d+e)=0.1˜0.5, and e/(a+b+c+d+e)=0.01˜0.5.

2. The photosensitive polymer according to claim 1, wherein the polymer has a weight average molecular weight of about 3,000 to about 100,000.

3. The photosensitive polymer according to claim 1, wherein R₄ is a group containing at least one structure selected from the group consisting of a hydroxy, carboxyl, ether, lactone and hyperlactone group.

4. The photosensitive polymer according to claim 3, wherein R₄ has at least one structure selected from the group consisting of

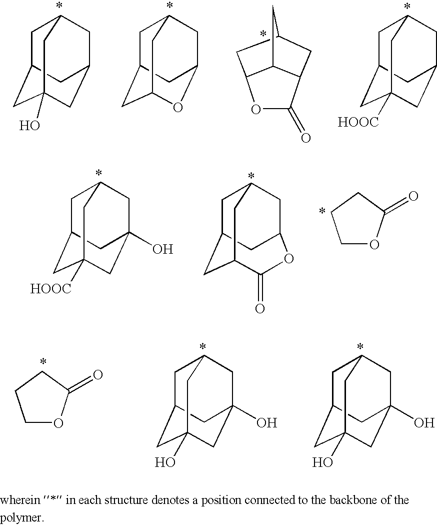

5. The photosensitive polymer according to claim 1, wherein R₃ is t-butyl.

6. The photosensitive polymer according to claim 1, wherein R₃ is tetrahydropyranyl.

7. The photosensitive polymer according to claim 1, wherein R₃ is an acid-labile alicyclic hydrocarbon group.

8. The photosensitive polymer according to claim 7, wherein R₃ is 2-methyl-2-norbornyl, 2-ethyl-2-norbornyl, 2-methyl-2-isobornyl, 2-ethyl-2-isobornyl, 8-methyl-8-tricyclo[5.2.1.0^{2,6}]decanyl, 8-ethyl-8-tricyclo[5.2.1.0^{2,6}]decanyl, 2-methyl-2-adamantyl, 2-ethyl-2-adamantyl, 2-methyl-2-fenchyl or 2-ethyl-2-fenchyl.

9. A resist composition comprising:
(a) a photosensitive polymer having a formula: 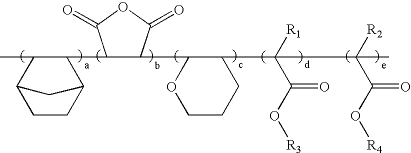
wherein R₁ and R₂ are independently a hydrogen atom or a methyl group, R₃ is an acid-labile C₄˜C₂₀ hydrocarbon group, R₄ is a hydrophilic group, a/(a+b+c+d+e)=0.01˜0.6, b/(a+b+c+d+e)=0.05˜0.7, c/(a+b+c+d+e)=0.01˜0.6, d/(a+b+c+d+e)=0.1˜0.5, and e/(a+b+c+d+e)=0.01˜0.5; and
(b) a photoacid generator (PAG).

10. The resist composition according to claim 9, wherein the photosensitive polymer has a weight average molecular weight of about 3,000 to about 100,000.

11. The resist composition according to claim 9, wherein R₄ is a group containing at least one structure selected from the group consisting of a hydroxy, carboxyl, ether, lactone and hyperlactone group.

12. The resist composition according to claim 11, wherein R₄ has at least one structure selected from the group consisting of

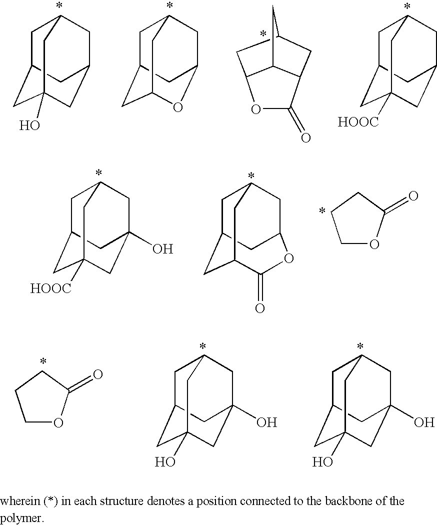

13. The resist composition according to claim 9, wherein R₃ is t-butyl.

14. The resist composition according to claim 9, wherein R₃ is tetrahydropyranyl.

15. The resist composition according to claim 9, wherein R₃ is an acid-labile alicyclic hydrocarbon group.

16. The resist composition according to claim 15, wherein R₃ is 2-methyl-2-norbornyl, 2-ethyl-2-norbornyl, 2-methyl-2-isobornyl, 2-ethyl-2-isobornyl, 8-methyl-8-tricyclo[5.2.1.0^{2,6}]decanyl, 8-ethyl-8-tricyclo[5.2.1.0^{2,6}]decanyl, 2-ethyl-2-adamantyl, 2-ethyl-2-adamantyl, 2-methyl-2-fenchyl or 2-ethyl-2-fenchyl.

17. The resist composition according to claim 9, wherein the PAG is contained in an amount of about 0.5 to about 20 wt % based on the total weight of the photosensitive polymer.

18. The resist composition according to claim 9, wherein the PAG comprises triarylsulfonium salts, diaryliodonium salts, sulfonates or any combination thereof.

19. The resist composition according to claim 9, further comprising an organic base.

20. The resist composition according to claim 19, wherein the organic base is contained in an amount of about 0.5 to about 50 mol % based on the amount of the PAG.

21. The resist composition according to claim 19, wherein the organic base includes a tertiary amine compound.

22. The resist composition according to claim 19, wherein the organic base is triethylamine, triisobutylamine, triisooctylamine, triisodecylamine, diethanolamine, triethanolamine, N-alkyl substituted pyrrolidinone, N-alkyl substituted caprolactam, N-allyl caprolactam, N-alkyl substituted valerolactam or any combination thereof.
